(19) United States
(12) Patent Application Publication
(10) Pub. No.: US 2024/0321792 A1
(43) Pub. Date: Sep. 26, 2024

(54) SEMICONDUCTOR PACKAGE

(71) Applicant: Samsung Electronics Co., Ltd., Suwon-si (KR)

(72) Inventor: Duckgyu Kim, Suwon-si (KR)

(21) Appl. No.: 18/607,941

(22) Filed: Mar. 18, 2024

(30) Foreign Application Priority Data
Mar. 24, 2023 (KR) 10-2023-0039187
May 18, 2023 (KR) 10-2023-0064561

(51) Int. Cl. H01L 23/00

(52) U.S. Cl. CPC H01L 24/05; H01L 2224/02255; H01L 2224/0401; H01L 2224/05166; H01L 2224/05555; H01L 2224/05557; H01L 2924/0495; H01L 2924/0509; H01L 2924/05341

(57) ABSTRACT

Provided is a semiconductor package including a semiconductor chip, a pad structure electrically connected to the semiconductor chip, a solder ball spaced apart from the semiconductor chip in a first direction and in contact with the pad structure, and an insulating layer arranged between the semiconductor chip and the pad structure and in contact with the pad structure, wherein the insulating layer includes a first ring-shaped groove having a ring shape surrounding the pad structure, and the first ring-shaped groove is spaced apart from the pad structure.

### CROSS-REFERENCE TO RELATED APPLICATION

This application is based on and claims priority under 35 U.S.C. § 119 to Korean Patent Application No. 10-2023-0039187, filed on Mar. 24, 2023, and Korean Patent Application No. 10-2023-0064561, filed on May 18, 2023, in the Korean Intellectual Property Office, the disclosures of which are incorporated by reference herein in their entireties.

### BACKGROUND

The inventive concept relates to a semiconductor package, and more particularly, to a wafer-level-package (WLP).

A WLP method is a method of packaging a semiconductor chip without a printed circuit board (PCB), by using a redistribution layer. Such a WLP method may provide a semiconductor package that has a small planar area, a small thickness, a fast speed, and a great bandwidth, compared to an existing packaging method.

### SUMMARY

The inventive concept provides a semiconductor package in which the reliability thereof is improved.

According to an aspect of the inventive concept, there is provided a semiconductor package including a semiconductor chip, a pad structure electrically connected to the semiconductor chip, a solder ball spaced apart from the semiconductor chip in a first direction and in contact with the pad structure, and an insulating layer arranged between the semiconductor chip and the pad structure and in contact with the pad structure, wherein the insulating layer includes a first ring-shaped groove having a ring shape surrounding the pad structure, and the first ring-shaped groove is spaced apart from the pad structure.

According to another aspect of the inventive concept, there is provided a semiconductor package including a semiconductor chip providing a first surface and a second surface, an under bump metallization (UBM) pad disposed on the first surface and electrically connected to the semiconductor chip, a solder ball spaced apart from the semiconductor chip in a first direction and in contact with the UBM pad, an insulating layer arranged between the semiconductor chip and the UBM pad, and a seed layer conformally arranged between the UBM pad and the insulating layer, wherein a first groove having a ring shape that surrounds the UBM pad is provided in an upper surface of the insulating layer that is orthogonal to the first direction, the first groove and the UBM pad are spaced apart from each other, and the first groove does not overlap the solder ball in the first direction.

According to another aspect of the inventive concept, there is provided a semiconductor package including a semiconductor chip providing a first surface and a second surface, an under bump metallization (UBM) pad having a ring shape and disposed on the first surface to be electrically connected to the semiconductor chip, a UBM via integrated with the UBM pad and extending towards the semiconductor chip, a solder ball spaced apart from the semiconductor chip in a first direction and in contact with the UBM pad, and an insulating layer arranged between the semiconductor chip and the UBM pad and including an opening in which the UBM via is disposed, wherein a first groove having a ring shape is provided in an upper surface of the insulating layer that is orthogonal to the first direction, the first groove being spaced apart from the UBM pad by a fixed distance with the UBM pad at a center, and the first groove does not overlap the solder ball in the first direction.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to some embodiments;

FIG. 2 is an enlarged view of a region P of FIG. 1;

FIG. 3A is a plan view of a pad structure of a semiconductor package and a groove surrounding the pad structure, according to some embodiments;

FIG. 3B is a cross-sectional view taken along a line A-A′ of FIG. 3A;

FIG. 4A is a plan view of a pad structure of a semiconductor package and a groove surrounding the pad structure, according to some embodiments;

FIG. 4B is a cross-sectional view taken along a line B-B′ of FIG. 4A;

FIG. 5A is a plan view of a pad structure of a semiconductor package and a groove surrounding the pad structure, according to some embodiments;

FIG. 5B is a cross-sectional view taken along a line C-C′ of FIG. 5A;

FIG. 6A is a plan view of a pad structure of a semiconductor package and a groove surrounding the pad structure, according to some embodiments;

FIG. 6B is a cross-sectional view taken along a line D-D′ of FIG. 6A;

FIGS. 7 and 8 are cross-sectional views of semiconductor packages according to some embodiments; and

FIGS. 9A to 9K are cross-sectional views showing, in order, a method of manufacturing a semiconductor package, according to some embodiments.

### DETAILED DESCRIPTION

Hereinafter, some embodiments will be described with reference to accompanying drawings. However, the inventive concept is not limited to the embodiments described below, and may be embodied in other different forms including combinations of the described embodiments. The embodiments described below are provided to convey the scope of the inventive concept to one of ordinary skill in the art, and do not describe every permutation of the of the inventive concept.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” “planar,” “coplanar,” “parallel,” “uniform,” and “perpendicular,” as used herein encompass identicality or near identicality including variations that may occur, for example, due to manufacturing processes. The term “substantially” may be used herein to emphasize this meaning, unless the context or other statements indicate otherwise.

In the following description, common shapes may be used to describe different elements such as a ring, a cone, a circle, a plane, and/or other shapes. Such descriptions include not only elements that are identical to the described shape, but also include elements that are nearly identical including variations that may occur, for example, due to manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As used herein, “integrated” elements refers to elements that can be integrated with one another without a discontinuous boundary surface (for example, a grain boundary), in which two components formed by a different process are not simply in contact (discontinuity), but are formed of the same material by the same process.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

Items described in the singular herein may be provided in plural, as can be seen, for example, in the drawings. Thus, the description of a single item that is provided in plural should be understood to be applicable to the remaining plurality of items unless context indicates otherwise.

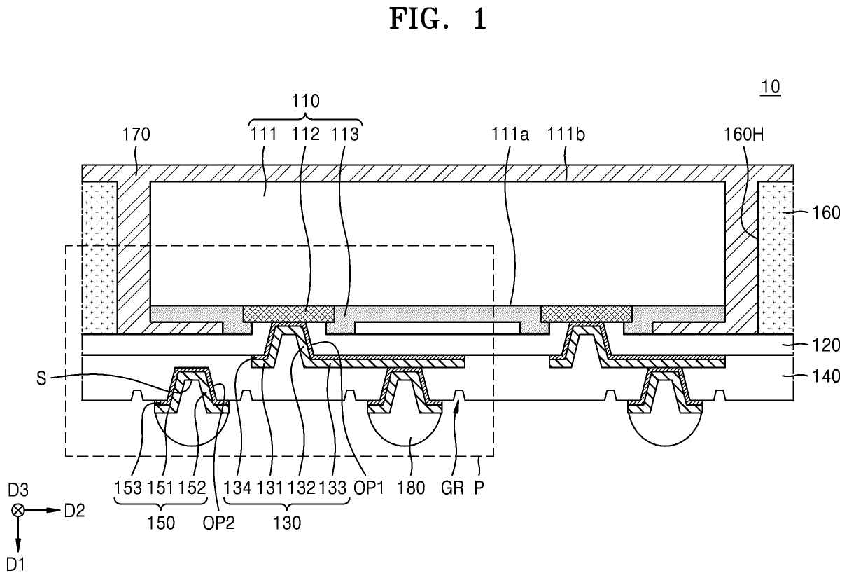

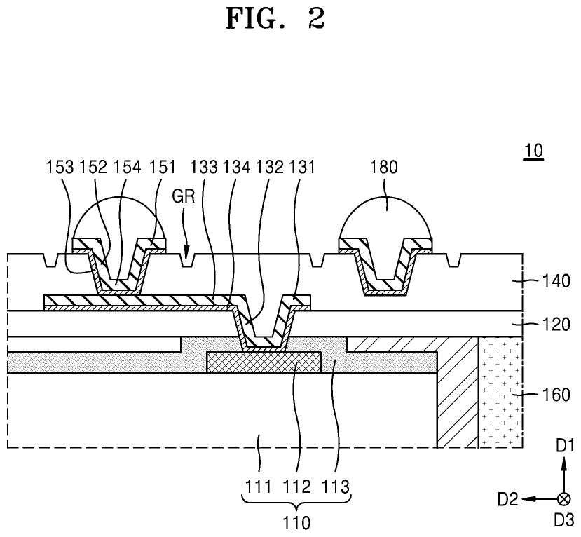

FIG. 1 is a cross-sectional view of a semiconductor package according to some embodiments, and FIG. 2 is an enlarged view of a region P of FIG. 1.

Referring to FIGS. 1 and 2, a semiconductor package 10 may include a semiconductor chip 110, a first insulating layer 120 disposed below the semiconductor chip 110, a second insulating layer 140, a redistribution layer structure 130 embedded in the first insulating layer 120 and the second insulating layer 140, and a pad structure 150 embedded in the second insulating layer 140. According to some embodiments, the semiconductor package 10 may further include a support member 160 disposed on the first insulating layer 120 and surrounding the semiconductor chip 110. According to some embodiments, the semiconductor package 10 may further include a molding layer 170 embedding the support member 160 and the semiconductor chip 110 on an upper surface of the first insulating layer 120.

The semiconductor chip 110 may include a body 111, a chip pad 112 on a lower surface of the body 111, and a passivation layer 113. The semiconductor chip 110 may include a first surface 111a where the chip pad 112 and the passivation layer 113 are located, and a second surface 111b on an opposite side of the semiconductor chip 110 from the first surface 111a. Here, the first surface 111a may be an active surface of the semiconductor chip 110 and the second surface 111b may be an inactive surface of the semiconductor chip 110.

The body 111 may include an integrated circuit. The integrated circuit may be any type of integrated circuit including a memory circuit, a logic circuit, or a combination thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. The logic circuit may include, for example, a central processing unit (CPU) circuit, a graphics processing unit (GPU) circuit, a controller circuit, an application specific integrated circuit (ASIC) circuit, an application processor (AP) circuit, or a combination thereof.

The integrated circuit may include a substrate. The substrate may be formed of and/or include a semiconductor material, for example, a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphide (InP), gallium phosphide (GaP), indium arsenide (InAs), indium antimonide (InSb), indium gallium arsenide (InGaAs), or a combination thereof. The group II-VI semiconductor material may include, for example, zinc telluride (ZnTe), cadmium sulfide (CdS), or a combination thereof.

The chip pad 112 may be used to electrically connect the semiconductor chip 110 to another element. The chip pad 112 may be formed of and/or include, for example, a conductive material including copper (Cu), aluminum (Al), silver (Ag), gold (Au), tungsten (W), titanium (Ti), or a combination thereof. The passivation layer 113 may protect the body 111. The passivation layer 113 may cover a lower surface of the body 111 and expose at least a portion of the chip pad 112. According to some embodiments, the passivation layer 113 may cover at least a portion of the chip pad 112. The passivation layer 113 may be formed of and/or include, for example, an insulating material that may be formed of and/or include an inorganic insulating material such as silicon oxide, silicon nitride, phosphosilicate glass (PSG), borophosphosilicate glass (BPSG), fluorosilicate glass (FSG), or a combination thereof, an organic insulating material such as insulating polymer, or a combination thereof.

The first insulating layer 120 and the second insulating layer 140 may be disposed on the first surface 111a of the semiconductor chip 110. According to some embodiments, planar areas (i.e., areas of cross-sections parallel to a second direction (direction D2) and a third direction (direction D3) of the first insulating layer 120 and the second insulating layer 140 may be greater than a planar area of the semiconductor chip 110. For example, the semiconductor package 10 may be a fan-out type.

A plurality of the redistribution layer structures 130 may be embedded in the first insulating layer 120 and the second insulating layer 140. In FIG. 1, the redistribution layer structures 130 having one vertical level are illustrated, but according to some embodiments, the semiconductor package 10 may include three or more insulating layers and include redistribution layer structures having two or more vertical levels.

The redistribution layer structure 130 may include a redistribution pad 131, a redistribution via 132, a redistribution pattern 133, and a first seed layer 134. The redistribution pad 131 may be disposed on a lower surface of the first insulating layer 120 (a surface forming an interface with the second insulating layer 140). The redistribution via 132 may extend towards the chip pad 112 of the semiconductor chip 110 through the first insulating layer 120. The redistribution pattern 133 may be elongated along a lower surface of the first insulating layer 120 by being integrated with the redistribution pad 131. The first seed layer 134 may extend along one surface of the redistribution pad 131, the redistribution via 132, and the redistribution pattern 133. The first seed layer 134 may be arranged between the redistribution pad 131 and the first insulating layer 120, between the redistribution via 132 and the first insulating layer 120, and between the redistribution pattern 133 and the first insulating layer 120. The first seed layer 134 may be a thin film compared to a thickness of the redistribution pattern 133.

The redistribution layer structures 130 may electrically connect the chip pad 112 of the semiconductor chip 110 to the pad structure 150. For example, the first insulating layer 120 may be disposed on the first surface 111a of the semiconductor chip 110 and may include a first opening OP1 exposing at least a portion of the chip pad 112 of the semiconductor chip 110. The first seed layer 134 may be elongated along the first opening OP1 of the first insulating layer 120 and a lower surface of the first insulating layer 120, and the redistribution via 132 may be formed on the first seed layer 134 inside the first opening OP1.

The redistribution pad 131, the redistribution via 132, and the redistribution pattern 133 of the redistribution layer structure 130 may be formed of and/or include, for example, a conductive material that may include copper (Cu), gold (Au), silver (Ag), nickel (Ni), tungsten (W), aluminum (Al), or a combination thereof.

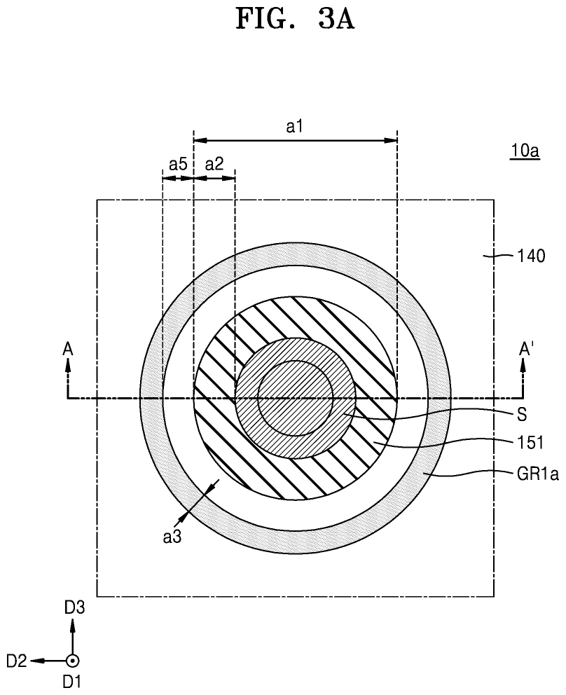

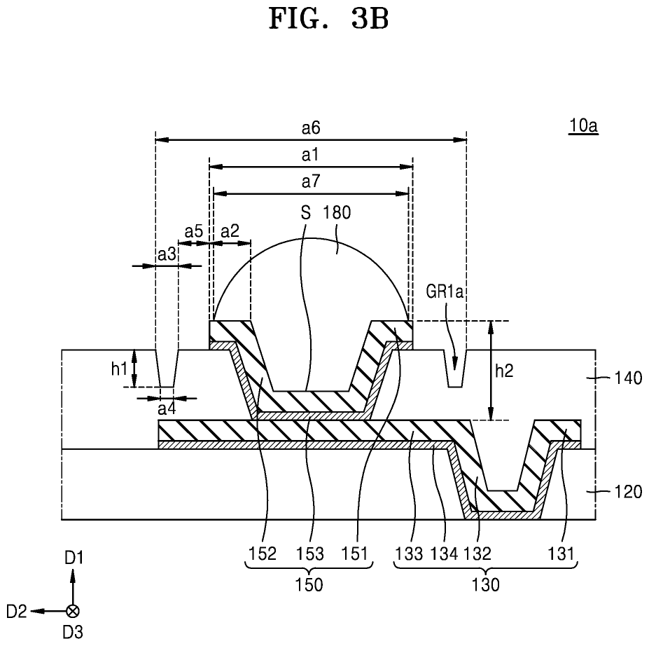

The pad structure 150 may include an under bump metallization (UBM) pad 151, a UBM via 152, and a second seed layer 153. The pad structure 150 may be disposed on an upper surface of the second insulating layer 140 (a surface facing a first direction (direction D1) and may include a second opening OP2 exposing at least a portion of the redistribution pattern 133 of the redistribution layer structure 130. The second seed layer 153 may be disposed on the second opening OP2 of the second insulating layer 140 and a portion of the upper surface of the second insulating layer 140. The second seed layer 153 may be a thin film compared to a thickness of the UBM pad 151. Details about the pad structure 150 will be described below with reference to FIGS. 3A and 3B.

The first and second insulating layers 120 and 140 may be formed of and/or include, for example, an insulating material that may include an inorganic insulating material such as silicon oxide, silicon nitride, phosphosilicate glass (PSG), borophosphosilicate glass (BPSG), fluorinated silicate glass (FSG), or a combination thereof, an organic insulating material such as insulating polymer, or a combination thereof. According to some embodiments, the first and second insulating layers 120 and 140 may be formed from a photosensitive material, for example, photosensitive polyimide. When the first and second insulating layers 120 and 140 are formed from a photosensitive material, it may be easy to form the first and second openings OP1 and OP2 in the first and second insulating layers 120 and 140.

A groove GR surrounding the pad structure 150 may be formed in an upper surface of the second insulating layer 140. Details about the groove GR will be described below with reference to FIGS. 3A and 3B.

A first groove GR1a shown in FIGS. 3A and 3B is an example of the groove GR shown in FIGS. 1 and 2. FIG. 3A is a plan view of the pad structure 150 of a semiconductor package 10a and the first groove GR1a surrounding the pad structure 150, according to some embodiments, and FIG. 3B is a cross-sectional view taken along line A-A′ of FIG. 3A.

The pad structure 150 may be disposed on a conductive pattern embedded in the first insulating layer 120 and a second insulating layer 140, i.e., on the redistribution layer structure 130, in the first direction (direction D1). The pad structure 150 may include the UBM pad 151 having a ring shape on a plane parallel to the second direction (direction D2) and the third direction (direction D3), the UBM via 152 integrated with the UBM pad 151 and penetrating through at least a portion of the second insulating layer 140, and the second seed layer 153 arranged between the UBM pad 151 and the second insulating layer 140, between the UBM via 152 and the second insulating layer 140, or between the UBM via 152 and the redistribution pattern 133. According to some embodiments, the UBM via 152 may have a truncated cone shape having a circular plane S.

The UBM pad 151 may have a ring shape on the upper surface of the second insulating layer 140 (a surface orthogonal to the direction D1). According to some embodiments, a maximum diameter a1 of the UBM pad 151 may be from 100 micrometers to 500 micrometers, for example, in some embodiments the maximum diameter may be from 200 micrometers to 250 micrometers, but according to another embodiment, the maximum diameter a1 of the UBM pad 151 may be less than 100 micrometers or greater 500 micrometers. When the maximum diameter a1 of the UBM pad 151 is decreased, a planar area of the semiconductor package 10a may be decreased and a contact area with a solder ball 180 may be decreased as well.

According to some embodiments, the UBM pad 151 may extend on the upper surface of the second insulating layer 140 (the surface orthogonal to the direction D1) with a uniform width a2. According to some embodiments, the width a2 of the UBM pad 151 may be from 10 micrometers to 50 micrometers, but according to another embodiment, the width a2 of the UBM pad 151 may be less than 10 micrometers or greater than 50 micrometers. When the width a2 of the UBM pad 151 is decreased, the planar area of the semiconductor package 10 may be decreased, but a process for forming the UBM pad 151 may become difficult.

According to some embodiments, the first groove GR1a having a ring shape surrounding the pad structure 150 may be formed in the upper surface of the second insulating layer 140. The first groove GR1a may be spaced apart from the pad structure 150 on the upper surface of the second insulating layer 140. Accordingly, the UBM pad 151 of the pad structure 150 may not extend into or above the first groove GR1a.

According to some embodiments, the first groove GR1a may be a ring-shaped groove having a tapered shape cross-section. The first groove GR1a may have uniform widths a3 and a4 in a circumferential direction with the pad structure 150 at a center of the ring of the ring-shaped groove. For example, the first groove GR1a may have a width in a radial direction, and the width a3 of the first groove GR1a in a level of the upper surface of the second insulating layer 140 may be greater than the width a4 of the first groove GR1a in a level farthest from the upper surface of the second insulating layer 140. For example, the first groove GR1a may have a tapered shape cross-section in which a width decreases away from the upper surface of the second insulating layer 140. For example, the first groove GR1a may have a width in the radial direction decreasing towards the semiconductor chip 110 in a range from the width a3 in the level of the upper surface of the second insulating layer 140 to the width a4 in the level farthest from the upper surface of the second insulating layer 140.

The first groove GR1a may be spaced apart from the UBM pad 151 of the pad structure 150 by a certain interval a5 (e.g., a fixed distance). Here, the interval a5 by which the first groove GR1a is spaced apart from the UBM pad 151 may be from 10 micrometers to 50 micrometers, but according to another embodiment, the interval a5 by which the first groove GR1a is spaced apart from the UBM pad 151 may be less than 10 micrometers or greater than 50 micrometers. When the interval a5 by which the first groove GR1a is spaced apart from the UBM pad 151 is decreased, there may be a reduction of stress focused between the pad structure 150 and the second insulating layer 140 as the stress becomes less focused, but a process for forming the first groove GR1 may become difficult.

According to some embodiments, a depth h1 of the first groove GR1a may be less than a length h2 of the pad structure in the first direction (e.g., a distance from a surface the first groove GR1a opens to a lower surface of the first groove GR1a may be less than the distance from the upper extent of the pad structure to the lower extent of the pad structure.)

According to some embodiments, a maximum diameter a6 of the first groove GR1a may be greater than the maximum diameter a1 of the UBM pad 151 and a diameter a7 of the solder ball 180. The first groove GR1a having the ring shape may not overlap the solder ball 180 in the first direction (direction D1) (e.g., the solder ball 180 may not be directly above the first groove GR1a). According to some embodiments, the maximum diameter a6 of the first groove GR1a may be from 150 micrometers to 1,000 micrometers, for example, in some embodiments from 250 micrometers to 500 micrometers, but according to other embodiments, the maximum diameter a6 of the first groove GR1a may be less than 150 micrometers or greater than 1,000 micrometers.

According to some embodiments, the second seed layer 153 may be arranged between the UBM pad 151 and the second insulating layer 140, between the UBM via 152 and the second insulating layer 140, and between the UBM via 152 and the redistribution pattern 133. In some embodiments, the second seed layer 153 may conform to a surface of the UBM pad 151 and the second insulating layer 140 (e.g., may be conformally arranged between the UBM pad 151 and the second insulating layer 140.) The second seed layer 153 may be in contact with the UBM pad 151 and the UBM via 152 and may be formed of and/or include at least one of titanium (Ti), titanium dioxide (TiO2), chromium nitride (CrN), titanium carbon nitride (TiCN), titanium aluminum nitride (TiAIN), and a combination thereof.

The second insulating layer 140 of the semiconductor package 10a may be the undermost insulating layer from among insulating layers configuring redistribution layers arranged below the semiconductor chip 110. Due to a difference in coefficients of thermal expansion between the pad structure 150 and the second insulating layer 140, stress may focus on an interface configured by the pad structure 150 and the second insulating layer 140, and excessive stress may cause corrosion or delamination of the pad structure 150. By forming the first groove GR1a having a ring shape in the second insulating layer 140 at a certain distance (e.g., a fixed distance) from the pad structure 150 with the pad structure 150 therebetween (e.g., the pad structure 150 is encompassed by the first groove GR1a), the stress focused on the interface between the pad structure 150 and the second insulating layer 140 may be distributed, and as a result, reliability of the semiconductor package 10a may be increased.

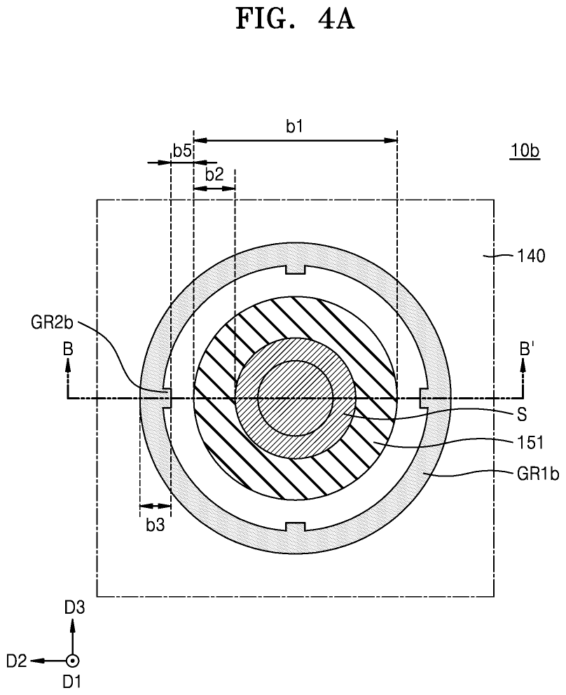

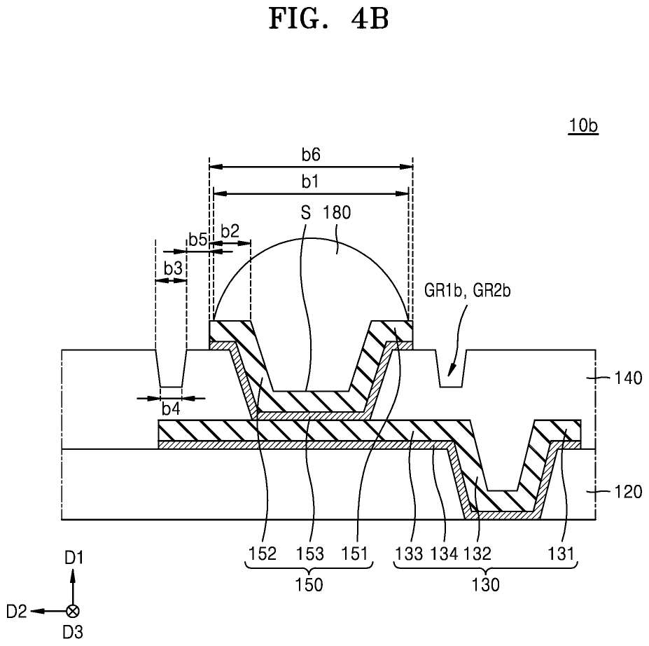

A first groove GR1b and a second groove GR2b shown in FIGS. 4A and 4B are examples of the groove GR shown in FIGS. 1 and 2. FIG. 4A is a plan view of the pad structure 150 of a semiconductor package 10b and a plurality of grooves, i.e., the first groove GR1b and the second groove GR2b surrounding the pad structure 150, according to another embodiment, and FIG. 4B is a cross-sectional view taken along a line B-B′ of FIG. 4A.

In the example of FIGS. 4A and 4B, the first groove GR1b has a ring shape and the second groove GR2b protrudes from (e.g., extends from) the first groove GR1b towards the pad structure 150. The second groove GR2b may be formed in the upper surface of the second insulating layer 140 of the semiconductor package 10b as shown in FIGS. 4A and 4B. Hereinafter, details about elements already illustrated and described in relation to FIGS. 3A and 3B may be omitted or briefly described.

The UBM pad 151 may have a ring shape on the upper surface of the second insulating layer 140. A maximum diameter b1 of the UBM pad 151 may be the same as the maximum diameter a1 of the UBM pad 151 described with reference to FIGS. 3A and 3B.

According to some embodiments, the UBM pad 151 may have a ring shape having a uniform width b2. According to another embodiment, the width b2 of the UBM pad 151 may not be uniform. The width b2 of the UBM pad 151 may be the same as the width a2 of the UBM pad 151 described with reference to FIGS. 3A and 3B.

According to some embodiments, the first groove GR1b having a ring shape surrounding the pad structure 150 may be formed in the upper surface of the second insulating layer 140. The first groove GR1b may be spaced apart from the pad structure 150 on the upper surface of the second insulating layer 140.

The first groove GR1b may be a ring-shaped groove having a tapered shape cross-section. The first groove GR1b may have a uniform width in the circumferential direction with the pad structure 150 at a center. However, as will be described below, the second groove GR2b protruding from the first groove GR1b towards the pad structure 150 may be formed in the upper surface of the second insulating layer 140 of the semiconductor package 10b according to some embodiments. Here, a sum b3 of widths of the first groove GR1b and the second groove GR2b in a level of the upper surface of the second insulating layer 140 may be greater than a sum b4 of widths of the first groove GR1b and the second groove GR2b in a level farthest from the upper surface of the second insulating layer 140. For example, the first groove GR1b and the second groove GR2b may have a tapered shape cross-section in which a width is decreased away from the upper surface of the second insulating layer 140.

According to some embodiments, the second groove GR2b protruding from the first groove GR1b towards the UBM pad 151 of the pad structure 150 may be formed in the upper surface of the second insulating layer 140 of the semiconductor package 10b shown in FIGS. 4A and 4B. The sum b3 of lengths of the first groove GR1b and the second groove GR2b in the radial direction may be greater than the width a3 of the first groove GR1a shown in FIGS. 3A and 3B. There may be a plurality of the second grooves GR2b, and as shown in FIG. 4B, the plurality of second grooves GR2b may consist of an even number of second grooves GR2b and pairs of second grooves GR2b may consist of two symmetrical second grooves GR2b on opposite sides of the ring shape of the first groove GR1b with the UBM pad 151 therebetween. However, according to other embodiments, the plurality of second grooves GR2b may consist of an odd number of second grooves GR2b and the second grooves GR2b of the plurality of the second grooves GR2b may not be arranged in symmetrical pairs with the UBM pad 151 therebetween.

According to some embodiments, the plurality of second grooves GR2b may be spaced apart from each other by a certain distance in the circumferential direction (e.g., a fixed distance which may be an angular distance such as 90 degrees), with the UBM pad 151 at a center.

By forming the second groove GR2b protruding from the first groove GR1b in the upper surface of the second insulating layer 140 of the semiconductor package 10b according to some embodiments, the stress that may have previously focused on the interface between the pad structure 150 and the second insulating layer 140 may be distributed to other areas. Accordingly, reliability of the semiconductor package 10b according to some embodiments may be increased.

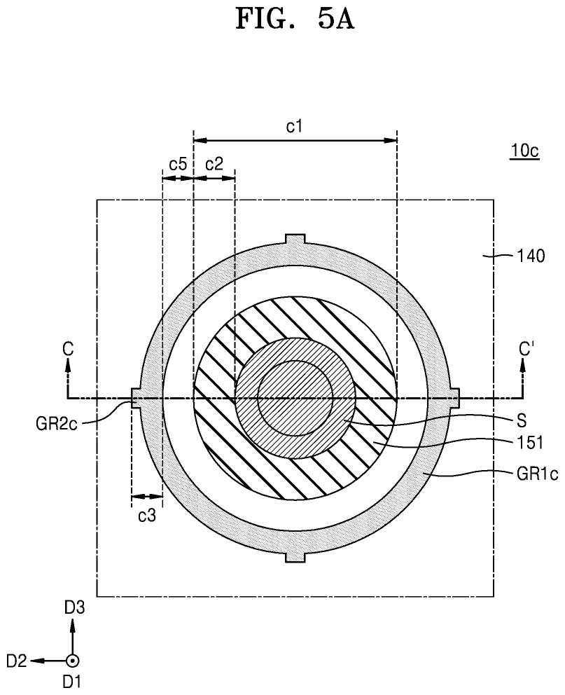

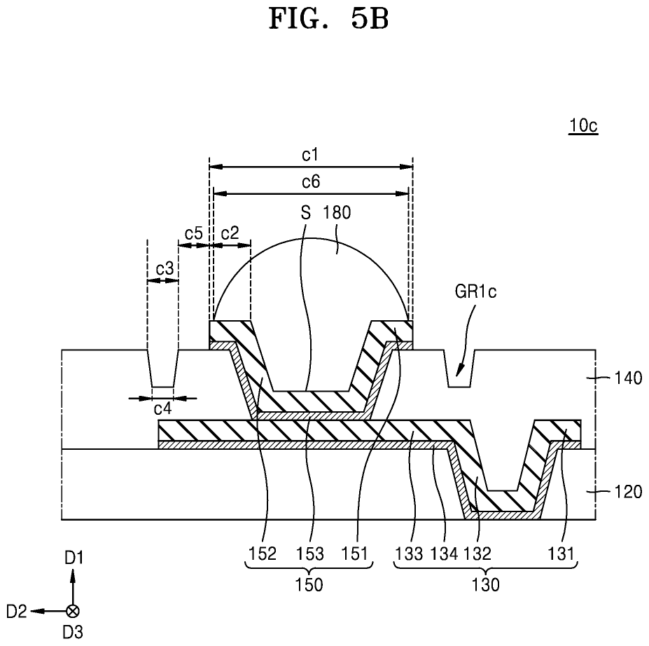

A first groove GR1c and a second groove GR2c shown in FIGS. 5A and 5B are examples of the groove GR shown in FIGS. 1 and 2. FIG. 5A is a plan view of the pad structure 150 of a semiconductor package 10c and the first groove GR1c and the second groove GR2c surrounding the pad structure 150, according to another embodiment, and FIG. 5B is a cross-sectional view taken along a line C-C′ of FIG. 5A.

In the embodiment shown in FIG. 5A, the first groove GR1c has a ring shape and the second groove GR2c protruding from (e.g., extending from) the first groove GR1c in the radial direction may be formed in the upper surface of the second insulating layer 140 of the semiconductor package 10c shown in FIGS. 5A and 5B. Hereinafter, details about elements already illustrated and/or described in relation to FIGS. 3A and 3B may be omitted or briefly described.

The UBM pad 151 may have a ring shape on an insulating layer. A maximum diameter c1 of the UBM pad 151 may be the same as the maximum diameter a1 of the UBM pad 151 described with reference to FIGS. 3A and 3B.

According to some embodiments, the UBM pad 151 may have a uniform width c2 on the upper surface of the second insulating layer 140. According to another embodiment, the width c2 of the UBM pad 151 may not be uniform. The width c2 of the UBM pad 151 may be the same as the width a2 of the UBM pad 151 described with reference to FIGS. 3A and 3B.

According to some embodiments, the first groove GR1c having a ring shape surrounding the pad structure 150 may be formed in the upper surface of the second insulating layer 140. The first groove GR1c may be spaced apart from the pad structure 150 on the upper surface of the second insulating layer 140.

The first groove GR1c may be a ring-shaped groove having a tapered shape cross-section. The first groove GR1c may have a uniform width in the circumferential direction with the pad structure 150 at a center of the ring-shape. A sum c3 of widths of the first groove GR1c and second groove GR2c in a level of the upper surface of the second insulating layer 140 may be greater than a sum c4 of widths of the first groove GR1c and second groove GR2c in a level farthest from the upper surface of the second insulating layer 140. For example, the first groove GR1c and the second groove GR2c may have a tapered shape cross-section in which a width is decreased away from the upper surface of the second insulating layer 140.

The first groove GR1c may be spaced apart from the UBM pad 151 of the pad structure 150 by a certain interval c5 (e.g., a fixed distance). The interval c5 by which the first groove GR1c is spaced apart from the UBM pad 151 of the pad structure 150 may be the same as the interval a5 by which the first groove GR1a is spaced apart from the UBM pad 151 as described with reference to FIGS. 3A and 3B.

According to some embodiments, a maximum diameter of the first groove GR1c may be greater than the maximum diameter c1 of the UBM pad 151 and a diameter c6 of the solder ball 180. The maximum diameter of the first groove GR1c may be the same as the maximum diameter a6 of the first groove GR1a described with reference to FIGS. 3A and 3B.

According to some embodiments, the second groove GR2c protruding from the first groove GR1c in the radial direction may be formed in the upper surface of the second insulating layer 140 of the semiconductor package 10c shown in FIGS. 5A and 5B. The sum c3 of lengths of the first groove GR1c and second groove GR2c in the radial direction may be greater than the width a3 of the first groove GR1a shown in FIGS. 3A and 3B. There may be a plurality of the second grooves GR2c, and in FIG. 5B, the plurality of second grooves GR2c may consist of even number of second grooves GR2c and pairs of second grooves GR2c may consist of two symmetric second grooves GR2c on opposite side of the ring shape of the first groove GR2c with the UBM pad 151 therebetween. However, according to some embodiments, the plurality of second grooves GR2c may consist of an odd number of second grooves GR2c and the second grooves GR2c may not be arranged in symmetrical pairs with the UBM pad 151 therebetween.

According to some embodiments, each the plurality of second grooves GR2c may be spaced apart from an adjacent second groove GR2c by a certain distance (e.g., an angular distance such as 90 degrees) in the circumferential direction, with the UBM pad 151 at a center.

By forming the second groove GR2c protruding from the first groove GR1c in the radial direction on the upper surface of the second insulating layer 140 of the semiconductor package 10c according to some embodiments, the stress that may have previously focused on the interface between the pad structure 150 and the second insulating layer 140 may be distributed to other areas. Accordingly, reliability of the semiconductor package 10c according to some embodiments may be increased.

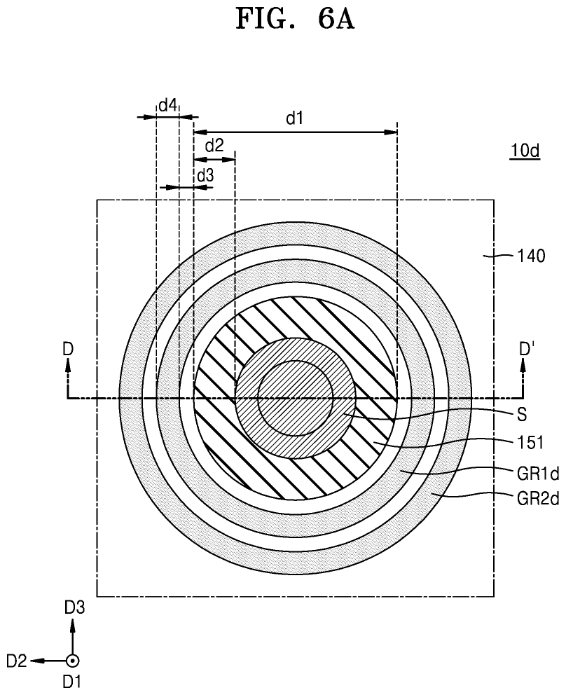

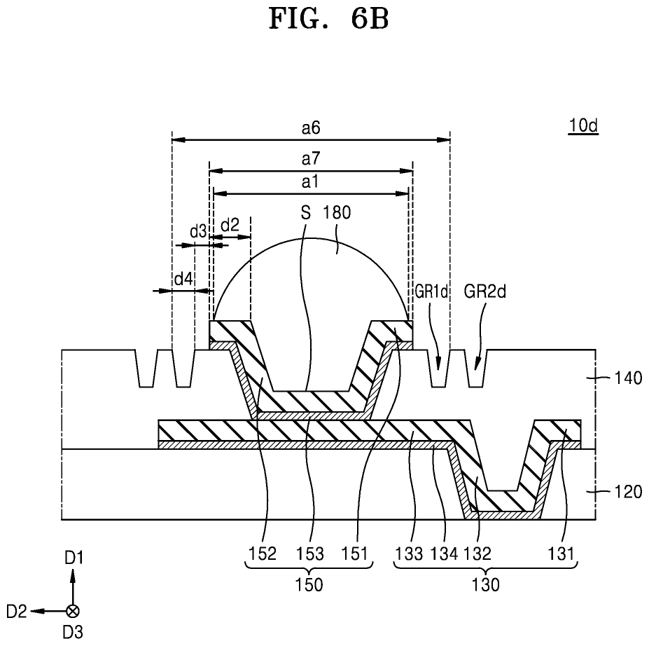

FIG. 6A is a plan view of the pad structure 150 of the semiconductor package 10d and first and second grooves GR1d and GR2d surrounding the pad structure 150, according to some embodiments, and FIG. 6B is a cross-sectional view taken along a line D-D′ of FIG. 6A.

In the example of FIGS. 6A and 6B, the first groove GR1d has a ring shape and the second groove GR2d has a ring shape as well that is spaced apart from the first groove GR1d in the radial direction. The first groove GR1d and the second groove GR2d may be formed in the upper surface of the second insulating layer 140 of the semiconductor package 10d as shown in FIGS. 6A and 6B. Hereinafter, details about elements already illustrated and described relation to FIGS. 3A and 3B may be omitted or briefly described.

The UBM pad 151 may have a ring shape on the upper surface of the second insulating layer 140. A maximum diameter d1 of the UBM pad 151 may be the same as the maximum diameter a1 of the UBM pad 151 described with reference to FIGS. 3A and 3B.

According to some embodiments, the UBM pad 151 may extend on the upper surface of the second insulating layer 140 with a uniform width d2. According to another embodiment, the width d2 of the UBM pad 151 may not be uniform. The width d2 of the UBM pad 151 may be the same as the width a2 of the UBM pad 151 described with reference to FIGS. 3A and 3B.

According to some embodiments, the first groove GR1d having a ring shape surrounding the pad structure 150 may be formed in the upper surface of the second insulating layer 140. The first groove GR1d may be spaced apart from the pad structure 150 in the upper surface of the second insulating layer 140.

The first groove GR1d may be spaced apart from the UBM pad 151 of the pad structure 150 by a certain interval d3 (e.g., a fixed distance). The interval d3 by which the first groove GR1d is spaced apart from the UBM pad 151 of the pad structure 150 may be less than the interval a5 by which the first groove GR1a is spaced apart from the UBM pad 151 as described with reference to FIGS. 3A and 3B. However, according to some embodiments, the interval d3 by which the first groove GR1d is spaced apart from the UBM pad 151 as shown in FIGS. 6A and 6B may be equal to or greater than the interval a5 by which the first groove GR1a is spaced apart from the UBM pad 151 as shown in FIGS. 3A and 3B.

According to some embodiments, the second groove GR2d having a ring shape and spaced apart from the first groove GR1d in the radial direction may be formed in the upper surface of the second insulating layer 140 of the semiconductor package 10d shown in FIGS. 6A and 6B. A width of the second groove GR2d in the radial direction may be the same as a width of the first groove GR1d in the radial direction.

By forming the second groove GR2d having a ring shape and spaced apart from the first groove GR1d in the radial direction, on the upper surface of the second insulating layer 140 of the semiconductor package 10d according to some embodiments, the stress that may have previously focused on the interface between the pad structure 150 and the second insulating layer 140 may be distributed to other areas. Accordingly, reliability of the semiconductor package 10d according to some embodiments may be increased.

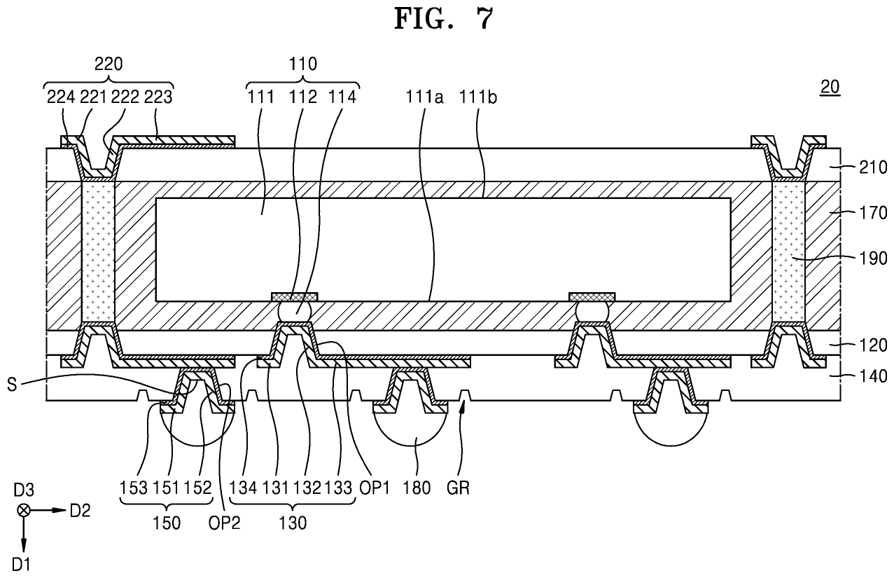

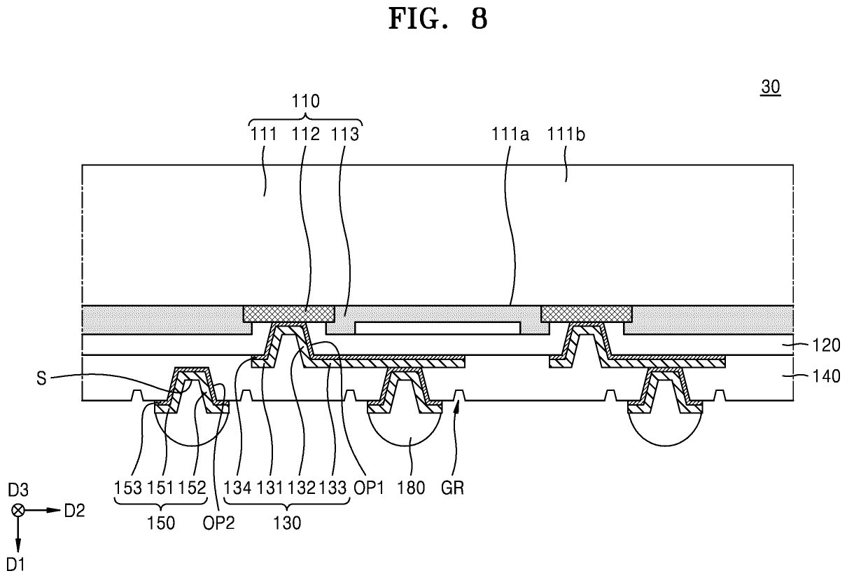

FIGS. 7 and 8 are cross-sectional views of semiconductor packages 20 and 30 according to other embodiments.

Referring to FIG. 7, the semiconductor package 20 shown in FIG. 7 is the same as or similar to the semiconductor package 10 shown in FIG. 1, except that the semiconductor package 20 further includes a vertical connection conductor 190, an upper insulating layer 210, and an upper redistribution layer structure 220 and does not include the support member 160. Accordingly, descriptions about elements that were already described with reference to FIG. 1 may be omitted below.

According to some embodiments, the semiconductor chip 110 of the semiconductor package 20 may include a chip connection terminal 114 physically and electrically connected to the redistribution layer structure 130 embedded in the first insulating layer 120 and the second insulating layer 140. Here, the chip connection terminal 114 may be in contact with the chip pad 112 of the semiconductor chip 110 and may function as an electric connection path between the semiconductor chip 110 and a conductor present outside the semiconductor chip 110. The chip connection terminal 114 may be formed of and/or include, for example, a conductive material that may include tin (Sn), lead (Pb), silver (Ag), copper (Cu), or a combination thereof.

According to some embodiments, the semiconductor package 20 may include the vertical connection conductor 190 which may surround the semiconductor chip 110 and perpendicularly penetrate the molding layer 170. Here, the vertical connection conductor 190 may be electrically connected to the redistribution layer structure 130 disposed on a lower surface of the semiconductor chip 110. The vertical connection conductor 190 may function as an electric connection path between the redistribution layer structure 130 and the upper redistribution layer structure 220 that will be described below. The vertical connection conductor 190 may be formed of and/or include a conductive material. For example, the vertical connection conductor 190 may be formed of and/or include a conductive material that may include copper (Cu), gold (Au), silver (Ag), nickel (Ni), tungsten (W), aluminum (Al), or a combination thereof. Unlike the semiconductor package 10 shown in FIG. 1, the semiconductor package 20 shown in FIG. 7 does not include the support member 160 surrounding the semiconductor chip 110, and the vertical connection conductor 190 may be formed by penetrating the molding layer 170 molding the semiconductor chip 110.

According to some embodiments, the semiconductor package 20 may include the upper insulating layer 210 disposed on an upper surface of the vertical connection conductor 190 and an upper surface of the molding layer 170. The upper insulating layer 210 may be arranged while having a uniform thickness along the upper surface of the molding layer 170 and the upper surface of the vertical connection conductor 190. The upper insulating layer 210 may be an insulating layer including the same insulating material as the first insulating layer 120 and the second insulating layer 140 described with reference to FIG. 1.

According to some embodiments, the semiconductor package 20 may include the upper redistribution layer structure 220 formed by penetrating the upper insulating layer 210. The upper redistribution layer structure 220 may include an upper redistribution pad 221, an upper redistribution via 222, an upper redistribution pattern 223, and an upper seed layer 224. The upper redistribution pad 221 may be disposed on an upper surface of the upper insulating layer 210. The upper redistribution via 222 may extend towards the vertical connection conductor 190 by penetrating the upper insulating layer 210. The upper redistribution pattern 223 may be elongated along the upper surface of the upper insulating layer 210 by being integrated with the upper redistribution pad 221. The upper seed layer 224 may extend along one surface of the upper redistribution pad 221, the upper redistribution via 222, and the upper redistribution pattern 223. In detail, the upper seed layer 224 may be arranged between the upper redistribution pad 221 and the upper insulating layer 210, between the upper redistribution via 222 and the upper insulating layer 210, and between the upper redistribution pattern 223 and the upper insulating layer 210. The upper seed layer 224 may be a thin film compared to a thickness of the upper redistribution pattern 223.

The semiconductor package 30 shown in FIG. 8 is almost the same as or similar to the semiconductor package 10 shown in FIG. 1, except that the semiconductor package 30 does not include the support member 160. Accordingly, descriptions about elements that are already described with reference to FIG. 1 may be omitted below. The semiconductor package 30 shown in FIG. 8 may be a fan in wafer level package (FIWLP).

Referring to FIG. 8, an upper surface of the semiconductor chip 110 of FIG. 8 may have the same area as an upper surface of the passivation layer 113, the first insulating layer 120, or the second insulating layer 140. The upper surface of the semiconductor chip 110 described herein denotes a surface orthogonal to a direction opposite to the first direction (direction D1) among surfaces of the semiconductor chip 110 having the greatest area.

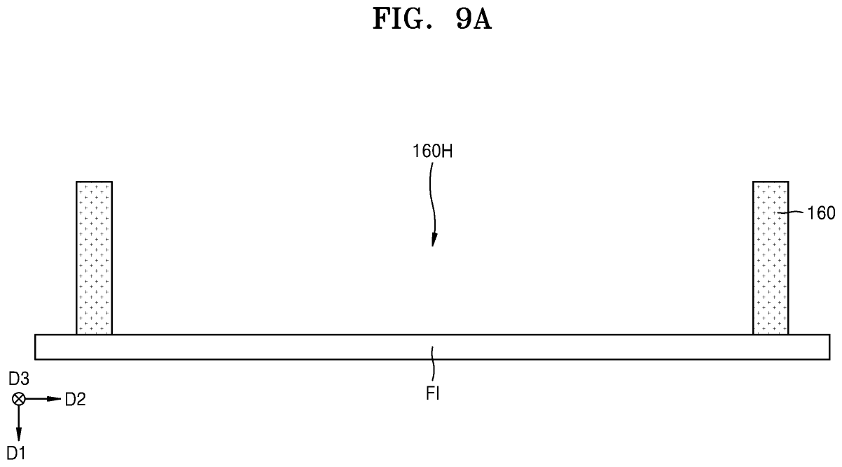

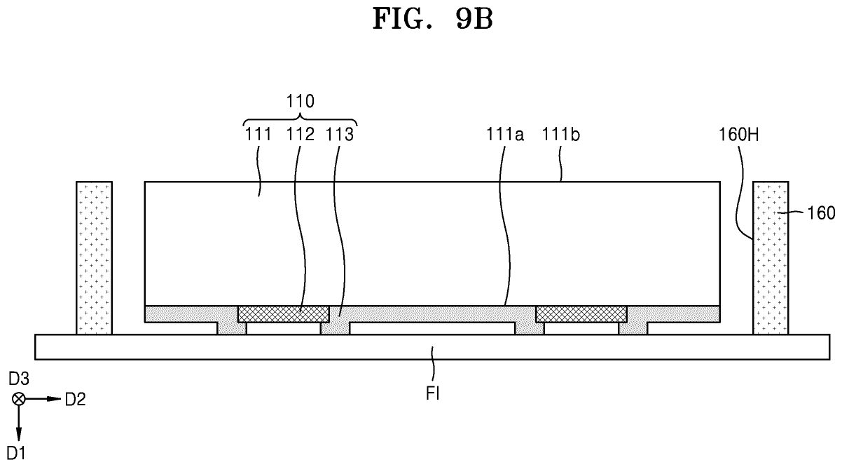

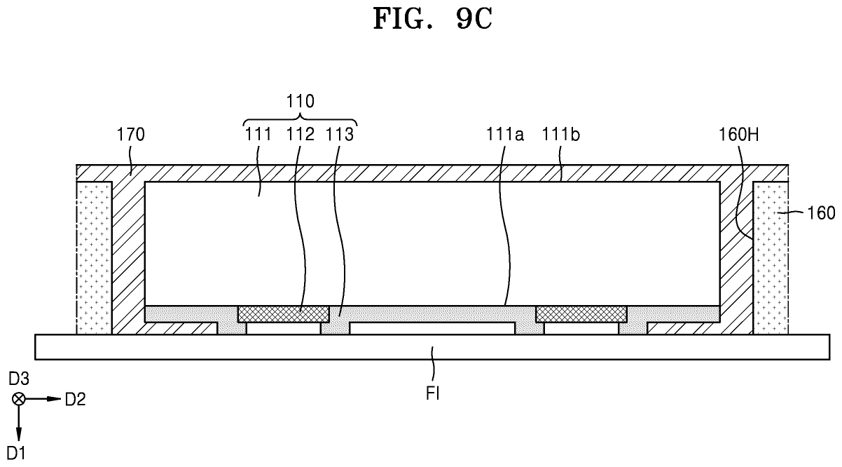

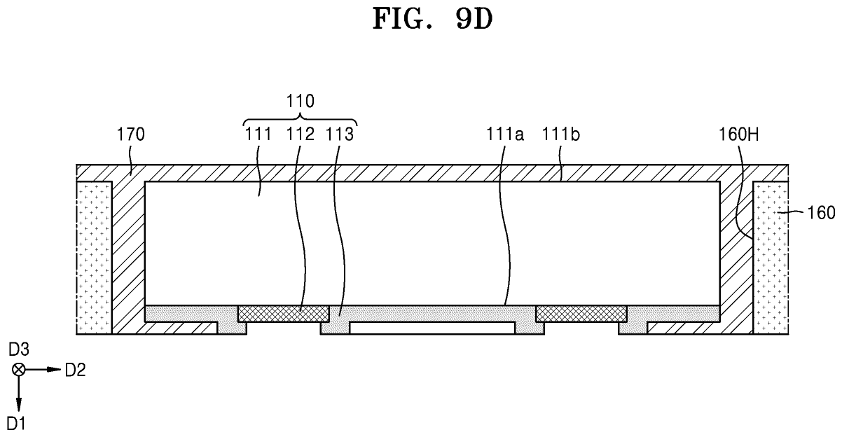

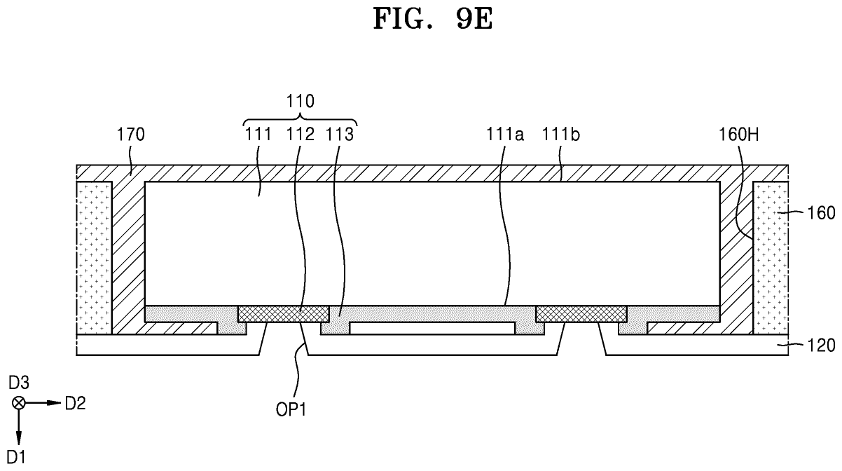

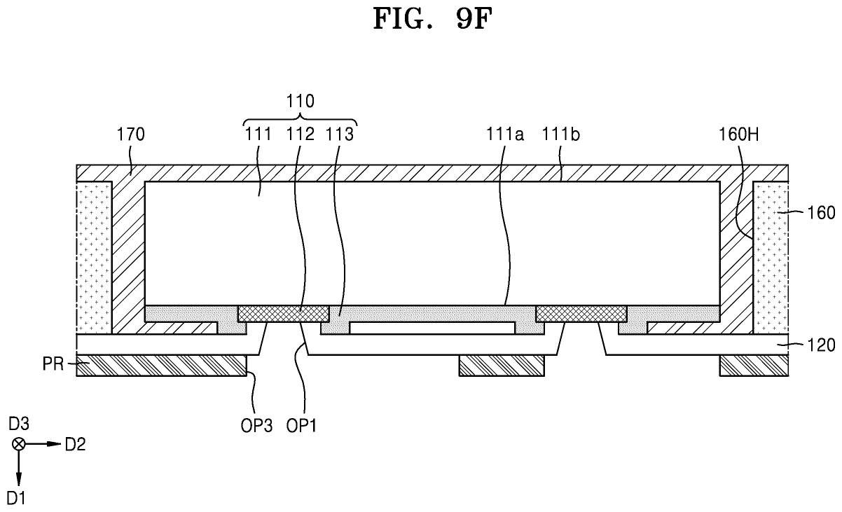

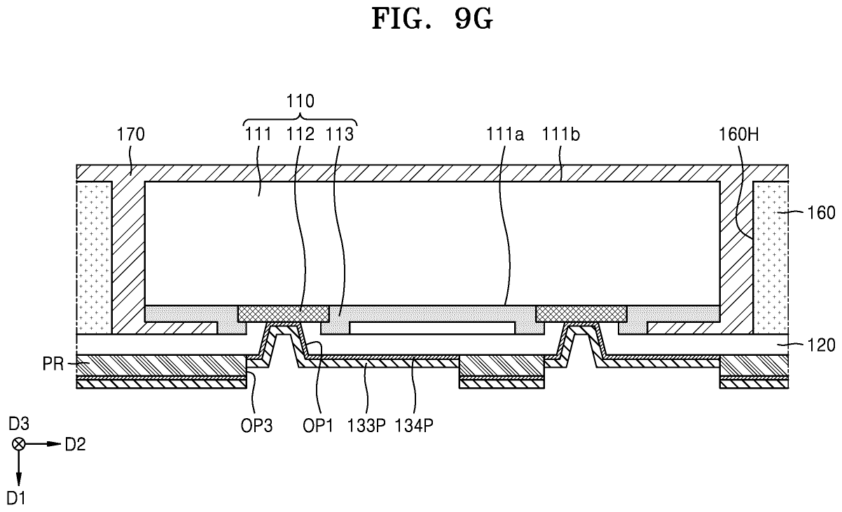

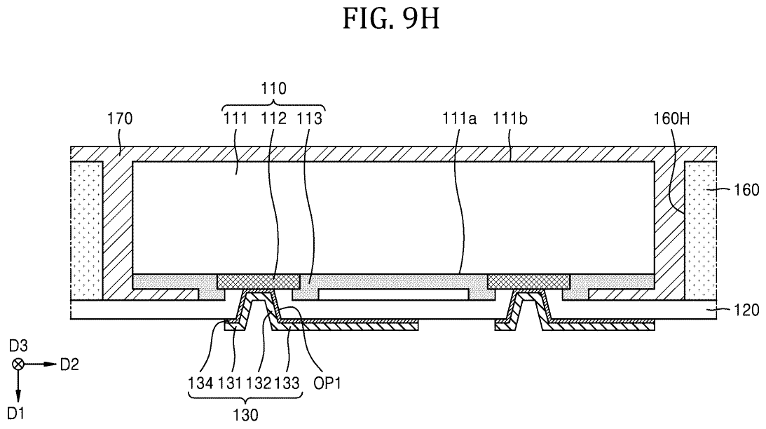

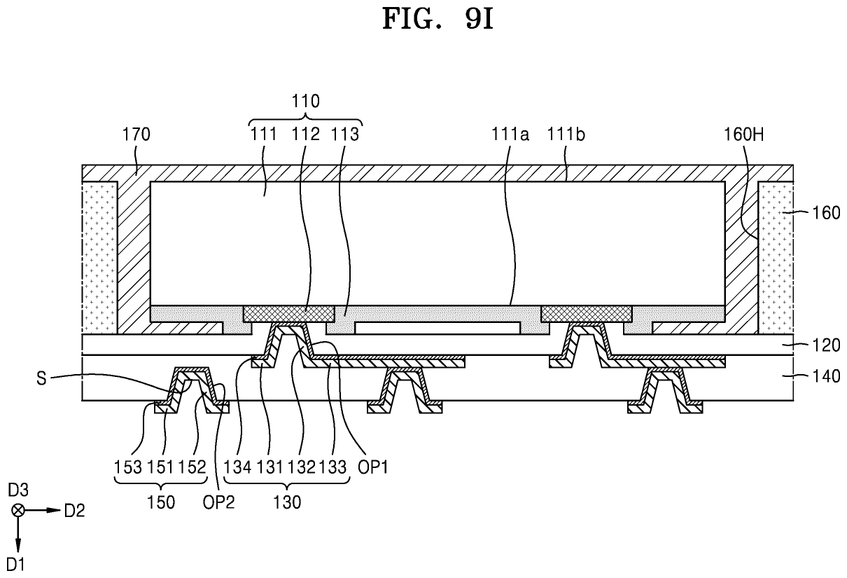

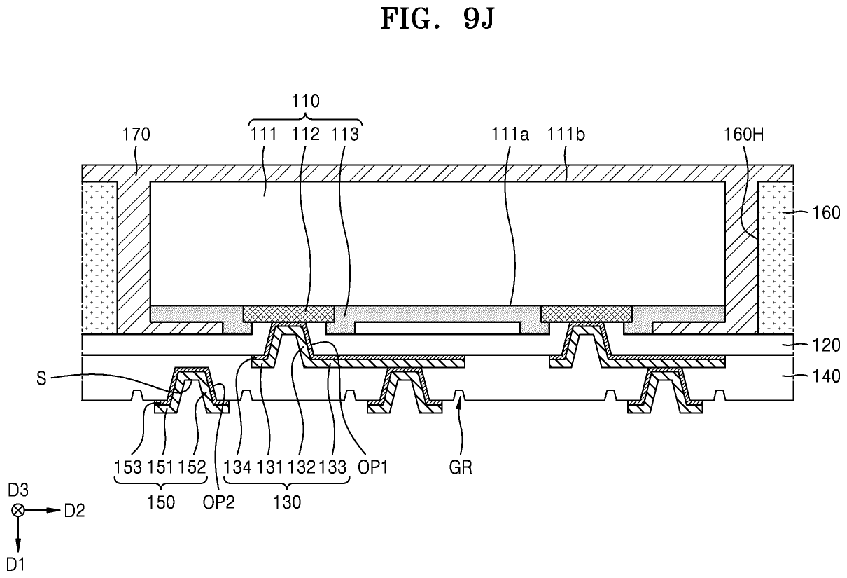

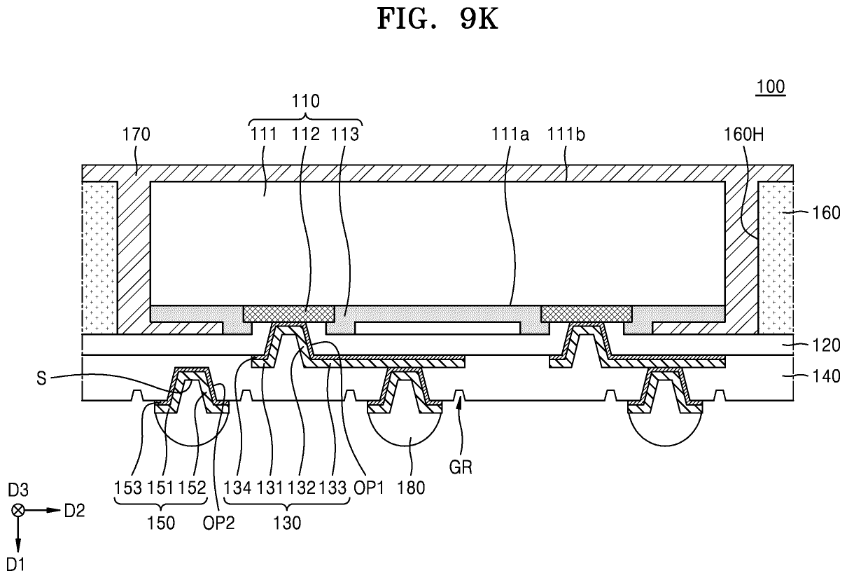

FIGS. 9A to 9K are cross-sectional views showing, in order, a method of manufacturing a semiconductor package, according to some embodiments.

Referring to FIG. 9A, a hole 160H penetrating the support member 160 is formed inside the support member 160. The hole 160H of the support member 160 may be formed by, for example, mechanical drilling, laser drilling, sand blast, dry etching, and/or wet etching. An adhesive film F1 is attached to one surface of the support member 160. The adhesive film F1 may be formed of and/or include an arbitrary material for fixing the support member 160. The adhesive film F1 may include, for example, a heat curable adhesive tape of which adhesive strength is weakened by heat treatment, or an ultraviolet curable adhesive tape of which adhesive strength is weakened by ultraviolet irradiation.

Referring to FIG. 9B, the semiconductor chip 110 is attached on the adhesive film F1 inside the hole 160H of the support member 160 such that the passivation layer 113 and the chip pad 112 of the semiconductor chip 110 face the adhesive film F1.

Referring to FIG. 9C, the molding layer 170 is formed that covers the semiconductor chip 110, the support member 160, and the adhesive film F1, and at least partially fills between the semiconductor chip 110 and the support member 160 and between the semiconductor chip 110 and the passivation layer 113. In some embodiments, the molding layer 170 may be formed by a well-known method. For example, the molding layer 170 may be formed by laminating molding precursors and then curing the same. Alternatively, the molding layer 170 may be formed by coating a molding material in a liquid state on the semiconductor chip 110, the support member 160, and the adhesive film F1, and then curing the molding material by using heat and/or ultraviolet rays.

Referring to FIGS. 9C and 9D, the adhesive film F1 may be delaminated from the semiconductor chip 110, the support member 160, and the molding layer 170, which in some embodiments may be according to a well-known method. For example, adhesive strength of the adhesive film F1 may be weakened by using heat and/or ultraviolet rays, and then the adhesive film F1 may be taken off.

Referring to FIG. 9E, the first insulating layer 120 may be formed on the semiconductor chip 110, the support member 160, and the molding layer 170. The first insulating layer 120 may be formed by, for example, lamination, coating, chemical vapor deposition (CVD), physical vapor deposition (PVD), or a combination thereof. The plurality of first openings OP1 exposing at least a portion of the chip pad 112 of the semiconductor chip 110 may be formed in the first insulating layer 120. The plurality of first openings OP1 may be formed by, for example, photolithography.

Referring to FIG. 9F, a photoresist pattern PR may be formed on the first insulating layer 120. For example, a photoresist layer may be formed on the first insulating layer 120 by spin coating, and the photoresist pattern PR may be formed from the photoresist layer by exposure and developing. The photoresist pattern PR may include a third opening OP3 exposing at least portions of the first insulating layer 120 and the chip pad 112 of the semiconductor chip 110.

Referring to FIG. 9G, a conductive layer 133P may be formed on the photoresist pattern PR, the first insulating layer 120, and the chip pad 112 of the semiconductor chip 110. For example, the conductive layer 133P may be formed by plating, CVD, PVD, or a combination thereof. After the conductive layer 133P is formed, a seed material 134P may be formed on the conductive layer 133P. For example, the seed material 134P may be formed by plating, CVD, PVD, or a combination thereof.

Referring to FIGS. 9G and 9H, the redistribution layer structure 130 may be formed by removing the photoresist pattern PR. The photoresist pattern PR may be removed by, for example, wet etching, dry etching, and/or ashing.

Referring to FIG. 91, in a similar manner as the first insulating layer 120, the second insulating layer 140 is formed on the first insulating layer 120 and the second opening OP2 exposing at least a portion of the redistribution layer structure 130 may be formed inside the second insulating layer 140. Then, as a similar method as forming of the redistribution layer structure 130, the pad structure 150 may be formed on the second insulating layer 140 and the redistribution layer structure 130. First, the second seed layer 153 may be formed in the second opening OP2 of the second insulating layer 140. The second seed layer 153 may be formed by, for example, plating, CVD, PVD, or a combination thereof. Next, the UBM via 152 and the UBM pad 151 may be formed on the second insulating layer 140 and the second seed layer 153. The UBM via 152 and the UBM pad 151 may be formed by plating, CVD, PVD, or a combination thereof.

Referring to FIG. 9J, the groove GR having a ring shape may be formed in the upper surface of the second insulating layer 140 with the pad structure 150 at a center. Here, the groove GR may be formed by, for example, a photolithography process.

Referring to FIG. 9K, the solder ball 180 may be placed on the UBM pad 151 of the pad structure 150. The solder ball 180 may be formed of and/or include, for example, a conductive material that may include tin (Sn), lead (Pb), silver (Ag), copper (Cu), or a combination thereof.

While the inventive concept has been particularly shown and described with reference to embodiments thereof, it will be understood that various changes in form and details may be made therein without departing from the spirit and scope of the following claims.

What is claimed is:

1. A semiconductor package comprising:
a semiconductor chip;
a pad structure electrically connected to the semiconductor chip;
a solder ball spaced apart from the semiconductor chip in a first direction and in contact with the pad structure; and
an insulating layer arranged between the semiconductor chip and the pad structure and in contact with the pad structure,
wherein the insulating layer includes a first ring-shaped groove having a ring shape surrounding the pad structure, and
the first ring-shaped groove is spaced apart from the pad structure.

2. The semiconductor package of claim 1, wherein the first ring-shaped groove does not overlap the solder ball in the first direction.

3. The semiconductor package of claim 1, wherein the pad structure comprises:
an under bump metallization (UBM) pad having a ring shape; and
a UBM via integrated with the UBM pad,
wherein the UBM pad does not extend to the first ring-shaped groove.

4. The semiconductor package of claim 3, wherein the pad structure further comprises a seed layer arranged between the UBM pad and the insulating layer or between the UBM via and the insulating layer,
wherein the seed layer comprises at least one of titanium (Ti), titanium dioxide (TiO2), chromium nitride (CrN), titanium carbon nitride (TiCN), and titanium aluminum nitride (TiAIN).

5. The semiconductor package of claim 1, wherein a depth of the first ring-shaped groove is less than a length of the pad structure in the first direction.

6. The semiconductor package of claim 1, wherein a width of the first ring-shaped groove in a radial direction decreases towards the semiconductor chip.

7. The semiconductor package of claim 1, wherein the first ring-shaped groove has a uniform width in a circumferential direction with the pad structure at a center of a ring shape of the ring-shaped groove.

8. The semiconductor package of claim 1, wherein the insulating layer comprises a second ring-shaped groove spaced apart from the first ring-shaped groove in a radial direction.

9. The semiconductor package of claim 8, wherein the second ring-shaped groove has a uniform width in a circumferential direction with the pad structure at a center of ring shape of the ring-shaped groove.

10. The semiconductor package of claim 1, wherein a maximum diameter of the first ring-shaped groove is greater than a diameter of the solder ball.

11. A semiconductor package comprising:
a semiconductor chip providing a first surface and a second surface;
an under bump metallization (UBM) pad disposed on the first surface and electrically connected to the semiconductor chip;
a solder ball spaced apart from the semiconductor chip in a first direction and in contact with the UBM pad;
an insulating layer arranged between the semiconductor chip and the UBM pad; and
a seed layer conformally arranged between the UBM pad and the insulating layer,
wherein a first groove having a ring shape that surrounds the UBM pad is provided in an upper surface of the insulating layer that is orthogonal to the first direction,
the first groove and the UBM pad are spaced apart from each other, and
the first groove does not overlap the solder ball in the first direction.

12. The semiconductor package of claim 11, wherein the UBM pad has a ring shape and a width of the UBM pad in a radial direction is greater than a maximum width of the first groove in the radial direction.

13. The semiconductor package of claim 11, wherein a second groove protruding from the first groove towards the UBM pad is provided in the upper surface of the insulating layer.

14. The semiconductor package of claim 13, further comprising:
a plurality of second grooves, wherein the second groove is among the plurality of second grooves,
wherein each second groove of the plurality of second grooves are spaced apart from an adjacent second groove by a fixed distance in a circumferential direction with the UBM pad at a center of the first groove.

15. The semiconductor package of claim 13, wherein the second groove is spaced apart from the UBM pad and does not overlap the solder ball in the first direction.

16. The semiconductor package of claim 11, wherein a second groove protruding from the first groove in a radial direction away from the UBM pad is provided in the upper surface of the insulating layer.

17. The semiconductor package of claim 16, further comprising:
a plurality of second grooves, wherein the second groove is among the plurality of second grooves,
wherein the plurality of second grooves includes pairs of second grooves, wherein each second groove of a pair of second grooves symmetrical to each other with respect to the UBM pad.

18. The semiconductor package of claim 11, wherein a width of the first groove in a radial direction decreases towards the semiconductor chip.

19. A semiconductor package comprising:
a semiconductor chip providing a first surface and a second surface;
an under bump metallization (UBM) pad having a ring shape and disposed on the first surface to be electrically connected to the semiconductor chip;
a UBM via integrated with the UBM pad and extending towards the semiconductor chip;
a solder ball spaced apart from the semiconductor chip in a first direction and in contact with the UBM pad; and
an insulating layer arranged between the semiconductor chip and the UBM pad and comprising an opening in which the UBM via is disposed,
wherein a first groove having a ring shape is provided in an upper surface of the insulating layer that is orthogonal to the first direction, the first groove being spaced apart from the UBM pad by a fixed distance with the UBM pad at a center of the first groove, and
the first groove does not overlap the solder ball in the first direction.

20. The semiconductor package of claim 19, wherein a plurality of second grooves protruding from the first groove towards the UBM pad are provided in the upper surface of the insulating layer, and
each of the plurality of second grooves are spaced apart from an adjacent second groove by a fixed circumferential distance in a circumferential direction.
